(19) United States
(12) Patent Application Publication
(10) Pub. No.: US 2015/0337459 A1
(43) Pub. Date: Nov. 26, 2015

(54) MULTILAYER THIN FILM FOR CUTTING TOOL AND CUTTING TOOL INCLUDING THE SAME

(71) Applicant: KORLOY INC., Seoul (KR)

(72) Inventors: Seung-Su AHN, Cheongju-si, Chungcheongbuk-do (KR); Je-Hun PARK, Cheongju-si, Chungcheongbuk-do (KR); Sung-Gu LEE, Cheongju-si, Chungcheongbuk-do (KR); Sun-Yong AHN, Cheongju-si, Chungcheongbuk-do (KR)

(21) Appl. No.: 14/653,266

(22) PCT Filed: May 21, 2013
(86) PCT No.: PCT/KR2013/004426

§ 371 Date: Jun. 18, 2015

(30) Foreign Application Priority Data
Dec. 27, 2012 (KR) 10-2012-0155125

(51) Int. Cl. C30B 29/38; C30B 29/68; C30B 25/10

(52) U.S. Cl. CPC C30B 29/38; C30B 25/105; C30B 29/68

(57) ABSTRACT

Provided is a multilayer thin film for a cutting tool, in which unit thin films each of which is formed of a total of four thin layers are stacked more than once, the multilayer thin film being capable of realizing improved physical properties compared with conventional one by adjusting an elastic period and a lattice period between the four thin layers. The multilayer thin film for a cutting tool according to the present disclosure is a multilayer thin film for a cutting tool, in which unit thin films each of which is sequentially stacked with thin layers A, B, C, and D are stacked more than once, wherein elastic modulus k between the thin layers satisfies relationships of k_{A}, k_{C}>k_{B}, k_{D} or k_{B}, k_{D}>k_{C}, k_{A}, and lattice parameter L between the thin layers satisfies relationships of L_{A}>L_{B}, L_{D}>L_{C} or L_{C}>L_{B}, L_{D}>L_{A}.

### TECHNICAL FIELD

The present disclosure relates to a multilayer thin film for a cutting tool, and more particularly, to a multilayer thin film for a cutting tool, in which superlattice thin films each having a thickness of a few nanometers to tens of nanometers are stacked in the form of A-B-C-D or A-B-C-B, being capable of realizing less quality variations and excellent wear resistance.

### BACKGROUND ART

Since the late 1980s, a variety of TiN-based multilayer film systems have been proposed in order to develop materials for a cutting tool having high hardness.

For example, a multilayer film formed by alternately and repeatedly stacking TiN or VN with a few nanometer thickness provides a coating formed of so-called superlattice having a single lattice parameter with coherent interfaces between layers despite a difference in lattice parameter of each single layer, and in this case, it is possible to realize twice or more high hardness compared with general hardness of each single layer. Accordingly, there have been various attempts for applying this phenomenon to thin films for cutting tools.

The principle that physical properties are improved in these superlattice coatings has been described as strengthening mechanisms such as a Koehler's model, a Hall-Petch relationship, and a Coherency strain model. These strengthening mechanisms are realized by controlling a difference in lattice parameter between A and B, a difference in elastic modulus between A and B, or a stacking period, upon alternate deposition of A and B materials.

In general, it is difficult to apply two or more mechanisms of the strengthening mechanisms through alternate stacking of two materials. Particularly, it is difficult to manufacture a multilayer thin film having excellent wear resistance with uniform quality under mass production conditions having severe deviations in a stacking period of the multilayer thin film between lots as well as in a lot.

Accordingly, in the formation of a multilayer thin film through alternate stacking of two or more materials as disclosed in U.S. Pat. No. 5,700,551, it was conventionally common that layers were stacked so that an elastic period (solid line) and a lattice period (dotted line) coincided with each other as illustrated in FIG. 1. However, in this case, it was difficult to simultaneously utilize the aforesaid various strengthening mechanisms, so that there has been a limitation in improving wear resistance of the multilayer thin film.

Furthermore, each thin film constituting the multilayer thin film formed through alternate stacking generally has a very small thickness of about a few nanometers to tens of nanometers, so that there is also a limitation in that physical properties of the multilayer thin film are deteriorated by inter-diffusion of components constituting the thin film between adjacent thin films when the multilayer thin film thus formed is exposed for a long time to a high temperature environment developed during the cutting.

### DISCLOSURE OF THE INVENTION

### Technical Problem

The purpose of the present disclosure is, in the formation of a multilayer thin film formed of a superlattice, to provide a multilayer thin film for a cutting tool, which has improved wear resistance compared with conventional superlattice coatings by adjusting a lattice period and an elastic period of the multilayer thin film so that two or more thin film strengthening mechanisms act on the multilayer thin film, and a cutting tool coated with the multilayer thin film.

Another purpose of the present invention is to provide a multilayer thin film in which inter-diffusion between thin layers constituting the multilayer thin film is prevented and the strengthening effect of the multilayer thin film may thus last for a long time compared with conventional one, and a cutting tool coated with the multilayer thin film.

### Technical Solution

In order to solve the above technical problem, the present disclosure provides a multilayer thin film for a cutting tool, in which unit thin films each of which is sequentially stacked with thin layers A, B, C, and D are stacked more than once, wherein elastic modulus k between the thin layers satisfies relationships of k_{A}, k_{C}>k_{B}, k_{D} or k_{B}, k_{D}>k_{C}, k_{A}, and lattice parameter L between the thin layers satisfies relationships of L_{A}>L_{B}, L_{D}>L_{C} or L_{C}>L_{B}, L_{D}>L_{A}.

In the multilayer thin film according to the present disclosure, it is preferable that a difference between maximum and minimum values of the lattice parameter L is 20% or less.

In the multilayer thin film according to the present disclosure, constituent elements of the thin layers B and D may be the same as constituent elements of the thin layers A and C which are adjacent to the thin layers B and D, or may include at least one of the constituent elements of the thin layers A and C.

In the multilayer thin film according to the present disclosure, an average lattice period λ_{L} of the multilayer thin film may be twice as large as an average elastic period λₖ thereof.

In the multilayer thin film according to the present disclosure, the unit thin film may have a thickness of 4 nm to 50 nm.

In the multilayer thin film according to the present disclosure, the thin layers B and D may be formed of the same material.

Furthermore, the present disclosure provides a cutting tool including the multilayer thin film.

### Advantageous Effects

The multilayer thin film, which is formed by controlling a difference in lattice parameter between thin layers constituting the multilayer thin film as well as a difference in elastic modulus according to the present disclosure, may simultaneously satisfy strengthening conditions for strengthening a thin film, such as a large difference in elastic modulus, minimization of a difference in lattice parameter between unit thin films, and minimization of a difference in thermal expansion coefficient between layers, so that the multilayer thin film thus formed may have further improved physical properties.

Furthermore, the multilayer thin film according to the present disclosure minimizes compositional differences between thin layers and thus prevents inter-diffusion between layers, thereby advantageously maintaining physical properties of the multilayer thin film for a long time even in a cutting environment at a high temperature.

Moreover, the multilayer thin film according to the present disclosure has improved physical properties by applying two or more strengthening mechanisms, so that quality variations are small even with a large difference in thin film thickness between lots. Therefore, the multilayer thin film is also advantageous in terms of productivity.

### BRIEF DESCRIPTION OF THE DRAWINGS

FIG. 1 shows a relationship between an elastic period and a lattice period in a conventional superlattice multilayer thin film.

FIG. 2 shows a relationship between an elastic period and a lattice period in a superlattice multilayer thin film according to the present disclosure.

FIG. 3 illustrates compositional differences between thin layers in a multilayer thin film according to the present disclosure.

FIG. 4 is a graph showing changes in lattice parameter according to aluminum content in a (Ti₁₋ₓAlₓ) N-based thin film.

FIG. 5 is photographs showing turning performance test results of a multilayer thin film according to Example 1 of the present disclosure and a multilayer thin film according to Comparative Example.

FIG. 6 is photographs showing milling performance test results of a multilayer thin film according to Example 1 of the present disclosure and a multilayer thin film according to Comparative Example.

FIG. 7 is photographs showing cutting performance test results of a multilayer thin film according to Example 2 of the present disclosure and a multilayer thin film according to Comparative Example.

### MODE FOR CARRYING OUT THE INVENTION

Hereinafter, the present disclosure will be described in detail based on exemplary embodiments thereof, but the inventive concept is not limited to the embodiments below.

The present inventors found that when an elastic period and a lattice period are adjusted differently with each other in the stacking of unit thin films instead of making the two periods coincide with each other, two or more strengthening mechanisms (i.e., the Koehler's model mechanism and the Hall-Petch relationship mechanism) may effectively act, particularly on a laminated superlattice thin film, and wear resistance of the multilayer thin film is thus improved and quality variations are also reduced in a mass production compared with a multilayer thin film on which a single strengthening mechanism mainly acts, and finally completed the present invention.

The multilayer thin film according to the present disclosure is a multilayer thin film, in which unit thin films each of which is sequentially stacked with thin layers A, B, C, and D are stacked more than once, wherein elastic modulus k between the thin layers satisfies relationships of k_{A}, k_{C}>k_{B}, k_{D} or k_{B}, k_{D}>k_{C}, k_{A}, and lattice parameter L between the thin layers satisfies relationships of L_{A}>L_{B}, L_{D}>L_{C} or L_{C}>L_{B}, L_{D}>L_{A}.

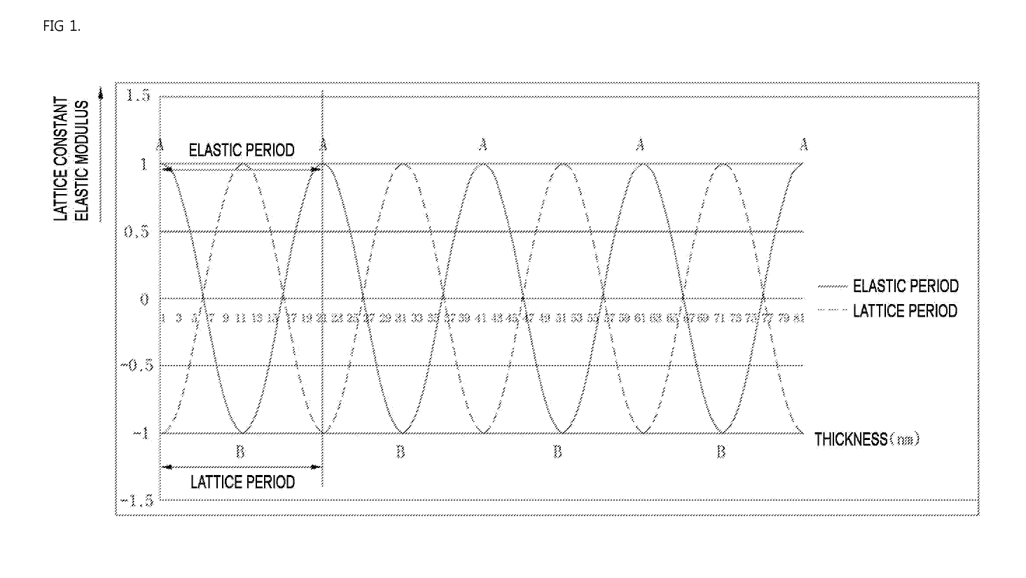

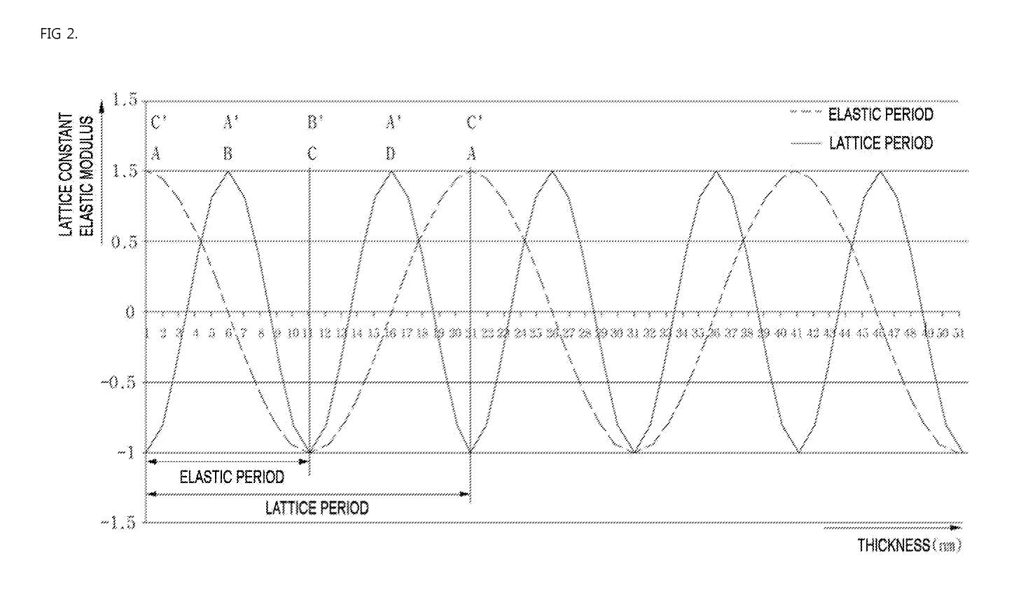

FIG. 2 shows an example of a relationship between an elastic period and a lattice period in a superlattice multilayer thin film according to the present disclosure. As shown in FIG. 2, it can be seen that the superlattice multilayer thin film according to the present disclosure is unlike in FIG. 1 in that the elastic period (solid line) is about twice as large as the lattice period (dotted line), and the elastic period and the lattice period thus do not coincide with each other.

In the Koehler model relating to elastic modulus, it is described that the strengthening effect is generated when thicknesses of thin films A and B become small enough to be less than or equal to 20 nm to 30 nm corresponding to a thickness of about 100 atomic layers, which is a critical thickness at which it is difficult to create dislocation. On the other hand, in the Hall-petch model which describes a material period distinguished due to a difference in lattice parameter, it is described that the strengthening effect is generated in a lower level, i.e., a period of a few nanometers. The inventive concept is that the elastic period and the lattice period are adjusted to be in discord with each other so that the two strengthening effects may be generated.

Also, when a difference between maximum and minimum values of the lattice parameter L is greater than 20%, it is difficult to form a superlattice. Therefore, it is preferable to adjust the lattice parameter so that the difference is generated in the range of 20% or less if possible.

The multilayer thin film according to the present disclosure is intended that the unit thin film is formed of four layers, and stacking in each unit thin film may be configured in the order of A-B-C-D or A-B-C-B. That is, second and fourth layers may be formed of different materials, or the same material.

Furthermore, a difference between an average elastic period and an average lattice period falls within the scope of the present disclosure, and preferably, the average elastic period may be twice as large as the average lattice period.

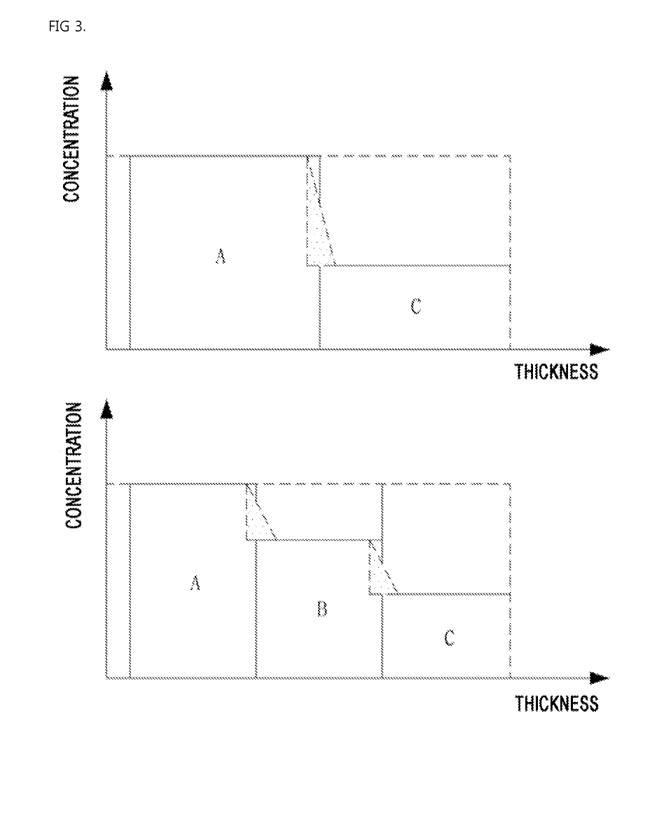

As illustrated in FIG. 3A, when concentration gradient between stacked thin layers (A layer-C layer) is large, a driving force inducing diffusion increases, so that probability of inter-diffusion becomes higher in long-time exposure to a cutting environment at a high temperature. On the other hand, as illustrated in FIG. 3B, when concentration gradient between stacked thin layers (A layer-B layer, B layer-C layer) is small, the driving force inducing diffusion decreases, and consequently inter-diffusion may also be delayed.

Accordingly, in order to reduce as much as possible the compositional difference between adjacent stacked thin layers, in the multilayer thin film according to the present disclosure, constituent elements of the thin layers B and D may be the same as constituent elements of the thin layers A and C which are adjacent to the thin layers B and D, or may include at least one of the constituent elements of the thin layers A and C.

### EXAMPLE 1

Prior to the formation of a superlattice multilayer thin film in which unit thin films each of which is formed of four thin layers are repeatedly stacked up to two or more layers, a monolayer thin film was deposited and elastic modulus of each thin layer constituting the unit thin film was measured in order to confirm the elastic modulus of each thin layer. The results are shown in Table 1.

An arc ion plating which is one of physical vapor deposition (PVD) methods was used for the deposition of the unit thin film. Initial vacuum pressure was reduced to 8.5×10⁻⁵ Torr or less, N₂ as a reaction gas was then injected, and deposition was conducted under conditions in which the reaction gas pressure was 40 mTorr or less (preferably 10 to mTorr), the temperature was 400 to 600° C., and the substrate bias voltage was −30 to −150 V.

TABLE 1

| Thin film | Target composition (at %) | Elastic modulus (GPa) |
|---|---|---|
| TiN | Ti = 99.9 | 416 |
| TiAlN | Ti:Al = 75:25 | 422 |
| TiAlN | Ti:Al = 50:50 | 430 |
| AlTiN | Ti:Al = 33:67 | 398 |
| TiAlCrN | Ti:Al:Cr = 28:67:5 | 404 |
| TiAlSiN | Ti:Al:Si = 35:63:2 | 374 |
| TiCrN | Ti:Cr = 90:10 | 421 |
| TiSiN | Ti:Si = 95:5 | 382 |
| TiVN | Ti:V = 95:5 | 412 |
| TiNbN | Ti:Nb = 95:5 | 406 |
| TiZrN | Ti:Zr = 95:5 | 377 |
| CrN | Cr = 99.9 | 475 |
| CrAlN | Cr:Al = 50:50 | 367 |
| AlCrN | Cr:Al = 30:70 | 403 |
| AlCrSiN | Cr:Al:Si = 30:65:5 | 338 |

The lattice parameter of each unit thin film constituting the multilayer thin film may be obtained using an XRD analysis following the formation of the monolayer thin film, but in the embodiment of the present disclosure, the lattice parameter of each unit thin film was determined using existing experiments and atomic, ionic, and covalent radii obtained from theories. Specifically, the lattice parameter was calculated by quantitatively applying the covalent radius to a B1 Cubic structure according to the atomic ratio

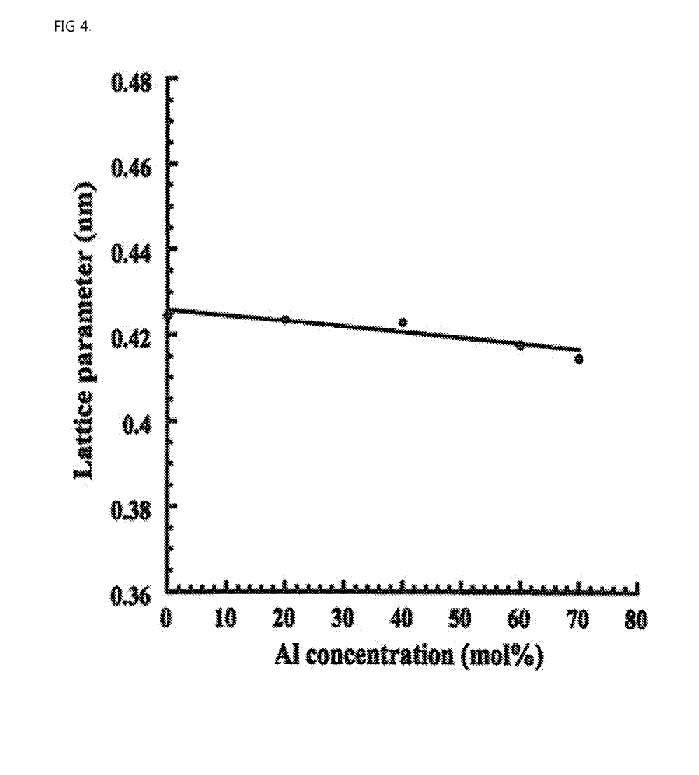

As shown in FIG. 4, in the case of the (Ti₁₋ₓAlₓ) N-based thin film, the lattice parameter tends to decrease approximately linearly as aluminum content increases, and the lattice parameter of the (Ti₁₋ₓAlₓ) N-based thin film may thus be obtained by Equation 1 below.

Lattice parameter: a=4.24−0.125x (x is a molar ratio of aluminum) [Equation 1]

In Example 1 of the present disclosure, a TiAlN-based multilayer thin film formed by the method according to the present disclosure was compared with a TiAlN-based multilayer thin film formed by a conventional method. An arc ion plating which is one of physical vapor deposition (PVD) methods was used for the deposition. Initial vacuum pressure was reduced to 4 mPa or less, and ion cleaning was performed on a substrate with −600 V. N₂ as a reaction gas was injected, and Ar and Kr were used as an inert gas. Deposition pressure was 500 to 700 mPa, and cathode power and rotational speed of table were respectively adjusted to be 2,000 to 14,000 W and 0.5 to 3 RPM in order to control the stacking period. Deposition was conducted under conditions in which the internal temperature of chamber was 400 to 600° C. and the substrate bias voltage was −60 to −150 V.

Stacking structures and compositions of the multilayer thin film were set as shown in Table 2 below. Unit thin films each of which was formed of four thin layers were repeatedly stacked a total of 200 times so that a period of the unit thin film formed of four thin layers was 10 to 20 nm, and a multilayer thin film having a final film thickness of 2.5 to 3.5 μm was thus obtained. In this case, a P30 Grade A30 material (Model No. SPKN1504EDSR-SM) available from Korloy was used as a substrate for milling, and an M30 Grade PP9030 material (Model No. CNMG120408-HS) available from Korloy was used as a substrate for turning.

TABLE 2

| Thin | | | | | | |
|---|---|---|---|---|---|---|
| film | Target | A | B | C | D | Remark |
| 1-1 | composition | Ti | Ti:Al = | Ti:Al = | Ti:Al = | Example |
| | | | 50:50 | 33:67 | 50:50 | |
| | Lattice | 462 | 423 | 409.7 | 423 | |
| | parameter | | | | | |
| | Elastic | 416 | 430 | 398 | 430 | |
| | modulus | | | | | |
| 1-2 | composition | Ti | Ti:Al = | Ti:Al = | Ti:Al = | Example |
| | | | 50:50 | 8:92 | 50:50 | |
| | Lattice | 462 | 423 | 390 | 423 | |
| | parameter | | | | | |
| | Elastic | 416 | 430 | 297 | 430 | |
| | modulus | | | | | |
| 1-3 | composition | Ti | Ti:Al = | Ti:Al:Si = | Ti:Al = | Example |
| | | | 50:50 | 35:63:2 | 50:50 | |
| | Lattice | 462 | 423 | 411 | 423 | |
| | parameter | | | | | |
| | Elastic | 416 | 430 | 374 | 430 | |
| | modulus | | | | | |
| 1-4 | composition | Ti | Ti:Al = | Ti:Al:Cr = | Ti:Al = | Example |
| | | | 50:50 | 28:67:5 | 50:50 | |
| | Lattice | 462 | 423 | 406 | 423 | |
| | parameter | | | | | |
| | Elastic | 416 | 430 | 404 | 430 | |
| | modulus | | | | | |
| 1-5 | composition | Ti:Cr = | Ti:Al = | Ti:Al = | Ti:Al = | Example |
| | | 90:10 | 50:50 | 33:67 | 50:50 | |
| | Lattice | 460 | 423 | 409.7 | 423 | |
| | parameter | | | | | |
| | Elastic | 421 | 430 | 398 | 430 | |
| | modulus | | | | | |
| 1-6 | composition | Ti:Si = | Ti:Al = | Ti:Al = | Ti:Al = | Example |
| | | 95:5 | 50:50 | 33:67 | 50:50 | |
| | Lattice | 459 | 423 | 409.7 | 423 | |
| | parameter | | | | | |
| | Elastic | 382 | 430 | 398 | 430 | |
| | modulus | | | | | |
| 1-7 | composition | Ti:V = | Ti:Al = | Ti:Al = | Ti:Al = | Example |
| | | 95:5 | 50:50 | 33:67 | 50:50 | |
| | Lattice | 461 | 423 | 409.7 | 423 | |
| | parameter | | | | | |
| | Elastic | 412 | 430 | 398 | 430 | |
| | modulus | | | | | |
| 1-8 | composition | Ti:Nb = | Ti:Al = | Ti:Al = | Ti:Al = | Example |
| | | 95:5 | 50:50 | 33:67 | 50:50 | |
| | Lattice | 462 | 423 | 409.7 | 423 | |
| | parameter | | | | | |
| | Elastic | 406 | 430 | 398 | 430 | |
| | modulus | | | | | |
| 1-9 | composition | Ti:Zr = | Ti:Al = | Ti:Al = | Ti:Al = | Example |
| | | 95:5 | 50:50 | 33:67 | 50:50 | |
| | Lattice | 464 | 423 | 409.7 | 423 | |
| | parameter | | | | | |
| | Elastic | 377 | 430 | 398 | 430 | |
| | modulus | | | | | |
| 1-10 | composition | Ti | Ti:Al = | Ti:Al = | Ti:Al = | Compara- |
| | | | 50:50 | 50:50 | 50:50 | tive |
| | Lattice | 462 | 423 | 423 | 423 | Example |
| | parameter | | | | | |
| | Elastic | 416 | 430 | 430 | 430 | |
| | modulus | | | | | |
| 1-11 | composition | Ti:Al = | Ti:Al = | Ti:Al = | Ti:Al = | Compara- |
| | | 33:67 | 50:50 | 50:50 | 50:50 | tive |
| | Lattice | 409.7 | 423 | 423 | 423 | Example |
| | parameter | | | | | |
| | Elastic | 398 | 430 | 430 | 430 | |
| | modulus | | | | | |
| 1-12 | composition | Ti:Al = | Ti:Al = | Ti:Al = | Ti:Al = | Compara- |
| | | 33:67 | 50:50 | 33:67 | 50:50 | tive |
| | Lattice | 409.7 | 423 | 409.7 | 423 | Example |
| | parameter | | | | | |
| | Elastic | 398 | 430 | 398 | 430 | |
| | modulus | | | | | |

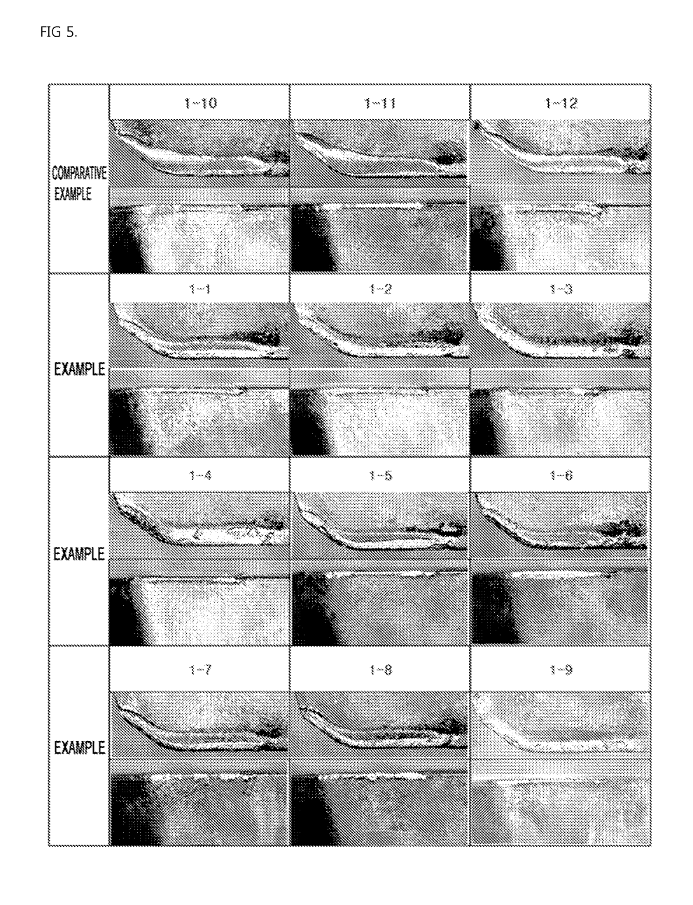

The cutting performance evaluation of the multilayer thin film deposited as above was conducted by way of milling and turning. In milling test, SKD11 (width: 100 mm, length: 300 mm) was used as a workpiece, and the cutting was conducted under the dry condition of a cutting speed of 250 m/min, a feed per tooth of 0.2 mm/tooth, and a feed of 2 mm. The milling performance was evaluated by comparing wear condition after the machining of 900 mm. The results are shown in FIG. 5.

As shown in FIG. 5, it can be seen that wear mainly proceeds as crater wear during the machining of SKD11, and it can be confirmed that the crater wear property is improved in Examples 1-1 to 1-9 compared with Comparative Examples 1-10 to 1-12.

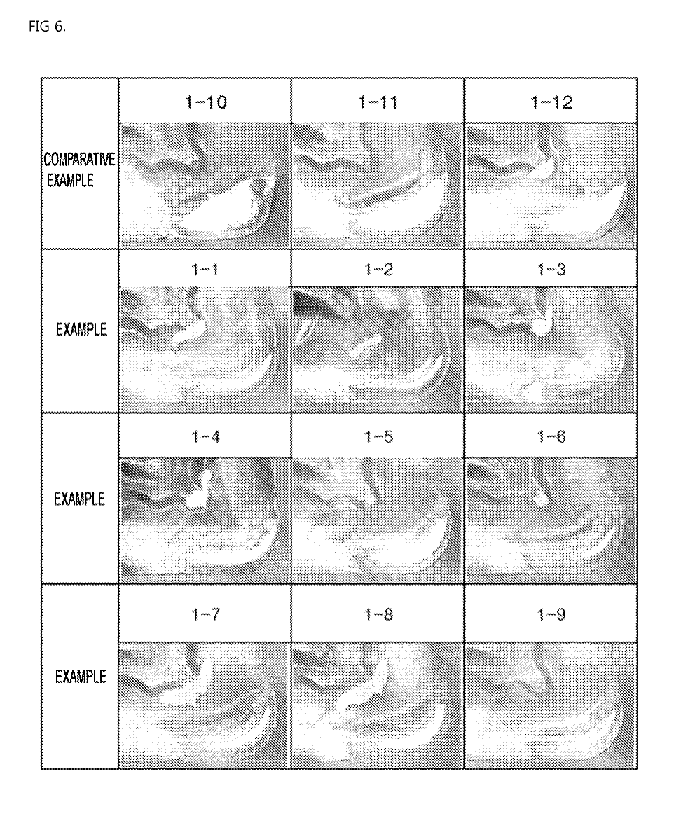

In turning test, STS316 was used as a workpiece, and the cutting was conducted under the wet condition of a cutting speed of 200 m/min, a feed per tooth of 0.25 mm/tooth, and a feed of 1.5 mm. The turning performance was evaluated by comparing wear condition after the continuous machining for 3 minutes. The results are shown in FIG. 6.

As shown in FIG. 6, it can be seen that wear mainly proceeds as crater wear during the machining of STS316, and it can be confirmed that the crater wear property is improved in Examples 1-1 to 1-9 compared with Comparative Examples 1-10 to 1-12.

### EXAMPLE 2

In Example 2 of the present disclosure, an AlCrN-based multilayer thin film formed by the method according to the present disclosure was compared with an AlCrN-based multilayer thin film formed by a conventional method.

Stacking structures and compositions of the multilayer thin film were set as shown in Table 3 below. Unit thin films each of which was formed of four thin layers were repeatedly stacked a total of 180 times so that the average lattice period was 5 to 10 nm and the elastic period was 10 to 20 nm, and a multilayer thin film having a final film thickness of 2.5 to 3.5 μm was thus obtained. In this case, an M30 Grade PP9030 material (Model No. CNMG120408-HS) available from Korloy was used as a substrate on which the multilayer thin film was deposited.

TABLE 3

| Thin | | | | | | |
|---|---|---|---|---|---|---|
| film | Item | A | B | C | D | Remark |
| 2-1 | composition | Cr = | Cr:Al = | Cr:Al = | Cr:Al = | Example |
| | | 99.9 | 50:50 | 30:70 | 50:50 | |
| | Lattice | 420 | 402 | 382.7 | 402 | |
| | parameter | | | | | |
| | Elastic | 475 | 367 | 403 | 367 | |
| | modulus | | | | | |
| 2-2 | composition | Cr:Si = | Cr:Al = | Cr:Al = | Cr:Al = | Example |
| | | 95:5 | 50:50 | 30:70 | 50:50 | |
| | Lattice | 417 | 402 | 382.7 | 402 | |
| | parameter | | | | | |
| | Elastic | 447 | 367 | 403 | 367 | |
| | modulus | | | | | |
| 2-3 | composition | Cr:Al = | Cr:Al = | Cr:Al = | Cr:Al = | Compara- |
| | | 30:70 | 50:50 | 30:70 | 50:50 | tive |
| | Lattice | 382.7 | 402 | 382.7 | 402 | Example |
| | parameter | | | | | |
| | Elastic | 403 | 367 | 403 | 367 | |
| | modulus | | | | | |

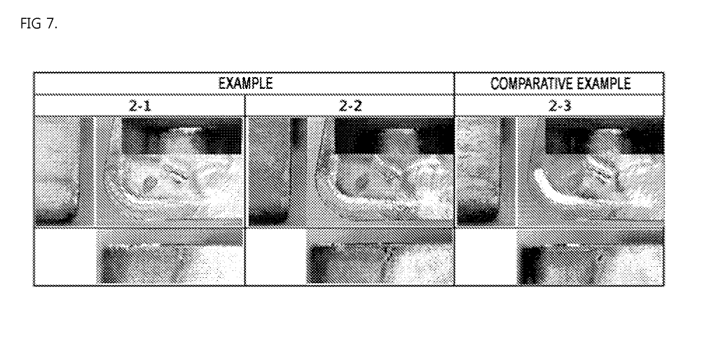

In the cutting performance evaluation of the multilayer thin film deposited as above, SM45C (diameter: 100 mm, height: 120 mm) was used as a workpiece, and the cutting was conducted under the dry condition of a cutting speed of 250 m/min, a feed per tooth of 0.25 mm/tooth, and a feed of 1.5 mm. Wear condition was compared after machining an end face 30 times. The results are shown in FIG. 7.

As shown in FIG. 7, Examples 2-1 and 2-2 of the present disclosure show improved crater wear form compared with Comparative Example 2-3.

In other words, it can be seen that a superlattice multilayer thin film stacked by controlling the elastic period and the lattice period according to the present disclosure exhibits improved wear resistance compared with otherwise cases.

### INDUSTRIAL APPLICABILITY

The multilayer thin film according to the present disclosure may be suitably used as a film for a cutting tool.

1. A multilayer thin film for a cutting tool, in which unit thin films each of which is sequentially stacked with thin layers A, B, C, and D are stacked more than once, wherein elastic modulus k between the thin layers satisfies relationships of k_{A},k_{C}>k_{B},k_{D} or k_{B},k_{D}>k_{C},k_{A}, and
lattice parameter L between the thin layers satisfies relationships of L_{A}>L_{B}, L_{D}>L_{C} or L_{C}>L_{B}, L_{D}>L_{A}.

2. The multilayer thin film of claim 1, wherein a difference between maximum and minimum values of the lattice parameter L is 20% or less.

3. The multilayer thin film of claim 1, wherein constituent elements of the thin layers B and D are the same as constituent elements of the thin layers A and C which are adjacent to the thin layers B and D, or include at least one of the constituent elements of the thin layers A and C.

4. The multilayer thin film of claim 1, wherein an average lattice period λ_{L} of the multilayer thin film is twice as large as an average elastic period λₖ thereof.

5. The multilayer thin film of claim 1, wherein the unit thin film has a thickness of 4 nm to 50 nm.

6. The multilayer thin film of claim 1, wherein the thin layers B and D are formed of the same material.

7. A cutting tool coated with the multilayer thin film of claim 1.

8. The multilayer thin film of claim 2, wherein the unit thin film has a thickness of 4 nm to 50 nm.

9. The multilayer thin film of claim 2, wherein the thin layers B and D are formed of the same material.

10. A cutting tool coated with the multilayer thin film of claim 2.
